(19) United States
(12) Patent Application Publication
(10) Pub. No.: US 2011/0249411 A1
(43) Pub. Date: Oct. 13, 2011

(54) Circuit Module and Electronic Apparatus

(76) Inventor: Shinya Hayashiyama, Tachikawa-shi (JP)

(21) Appl. No.: 13/008,703

(22) Filed: Jan. 18, 2011

(30) Foreign Application Priority Data
Apr. 12, 2010 (JP) 2010-091768

(51) Int. Cl. H05K 5/00; H05K 1/03

(52) U.S. Cl. 361/752; 174/255

(57) ABSTRACT

According to one embodiment, a circuit module is provided. The circuit module includes: a circuit board provided with a mounting region on which a heating element is mounted; a reinforcing portion which is attached to the circuit board and reinforces the mounting region; and four fixing portions which fixes the reinforcing portion and the circuit board. The reinforcing portion includes four beam portions connecting the four fixing portions like a frame. The four beam portions include two first-beam portions extending along a surface of the circuit board, and two second-beam portions floated up from the circuit board.

### CROSS REFERENCE TO RELATED APPLICATION(S)

The application is based upon and claims the benefit of priority from Japanese Patent Application No. 2010-091768 filed on Apr. 12, 2010; the entire content of which are incorporated herein by reference.

### FIELD

Embodiments described herein relate generally to a circuit module and an electronic apparatus which have a circuit board.

### BACKGROUND

A circuit board mounted on an electronic apparatus may be provided with a back plate.

### BRIEF DESCRIPTION OF THE DRAWINGS

FIG. 1 is a perspective view showing an electronic apparatus according to an exemplary embodiment;

FIG. 2 is a perspective view showing a first face of a circuit board according to the exemplary embodiment;

FIG. 3 is a top-plan view showing the first face of the circuit board shown in FIG. 2;

FIG. 4 is a perspective view showing the first face of the circuit board shown in FIG. 2;

FIG. 5 is a perspective view showing a second face of the circuit board shown in FIG. 2;

FIG. 6 is a top-plan view showing a second face of the circuit board shown in FIG. 2;

FIG. 7 is a cross-sectional view showing the circuit board shown in FIG. 6 at VII-VII line;

FIG. 8 is a cross-sectional view showing the circuit board shown in FIG. 6 at VIII-VIII line;

FIG. 9 is a cross-sectional view showing the circuit board shown in FIG. 6 at IX-IX line;

FIG. 10 is a perspective view showing a circuit board of a related art;

FIG. 11 is a top-plan view showing a circuit board of a first modification example according to the exemplary embodiment; and

FIG. 12 is a top-plan view showing a circuit board of a second modification example according to the exemplary embodiment.

### DETAILED DESCRIPTION

In general, according to one exemplary embodiment, a circuit module is provided. The circuit module includes: a circuit board provided with a mounting region on which a heating element is mounted; a reinforcing portion which is attached to the circuit board and reinforces the mounting region; and four fixing portions which fixes the reinforcing portion and the circuit board. The reinforcing portion includes four beam portions connecting the four fixing portions like a frame. The four beam portions include two first-beam portions extending along a surface of the circuit board, and two second-beam portions floated up from the circuit board.

Hereinafter, an exemplary embodiment of the present invention, which is applied to a notebook type personal computer (hereunder referred to as a notebook PC), is described with reference to the drawings.

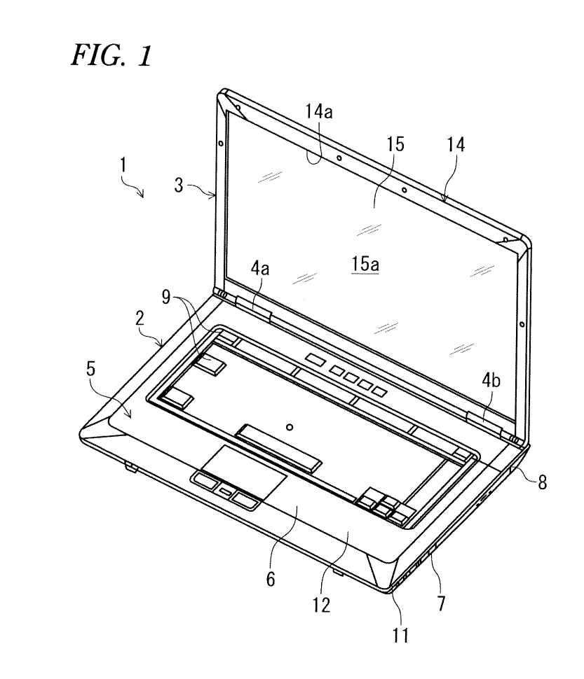

FIGS. 1 to 9 disclose an electronic apparatus 1 according to a first exemplary embodiment. The electronic apparatus 1 is, e.g., a notebook PC. An electronic apparatus to which the exemplary embodiment is applicable is not limited to the above one. The exemplary embodiment is applicable widely to various electronic apparatuses including, e.g., display apparatuses such as a television apparatus, a recording/reproducing apparatus, a personal digital assistant (PDA), and a game machine.

As shown in FIG. 1, the electronic apparatus 1 includes a body unit 2, a display unit 3, and hinges 4a and 4b. The body unit 2 is an electronic apparatus body on which a main board (circuit module) is mounted. The body unit 2 includes a case 5. The case 5 includes a top wall 6, a bottom wall 7, and a circumferential wall 8 and is shaped like a flat box.

When the electronic apparatus 1 is placed on a desk, the bottom wall 7 faces the top surface of the desk. The bottom wall 7 is substantially parallel to the top surface of the desk. The top wall 6 spreads substantially in parallel with the bottom wall 7 (i.e., substantially horizontally) by putting a space between the top wall 6 and the bottom wall 7. The top wall 6 is provided with a keyboard 9. FIG. 1 shows only a part of keys on the keyboard 9. The circumferential wall 8 is erected with respect to the bottom wall 7 and connects between the circumferential edge portion of the bottom wall 7 and that of the top wall 6.

The case 5 has a base 11 and a cover 12. The base 11 includes the bottom wall 7 and a part of the circumferential wall 8. The cover 12 includes the top wall 6 and a part of the circumferential wall 8. The case 5 is formed by combining the cover 12 with the base 11.

The display unit 3 is rotatably (openably/closably) connected to a rear end portion of the body unit 2 by the hinges 4a and 4b. The display unit 3 is rotatable between a closed position in which the display unit 3 is fallen flat to cover the body unit 2 from above, and an open position in which the display unit 3 is erected from the body unit 2.

As shown in FIG. 1, the display unit 3 includes a display case 14 and a display device 15 housed in the display case 14. A display screen 15a of the display device 15 can be exposed to the outside through an opening portion 14a provided in a front wall of the display case 5.

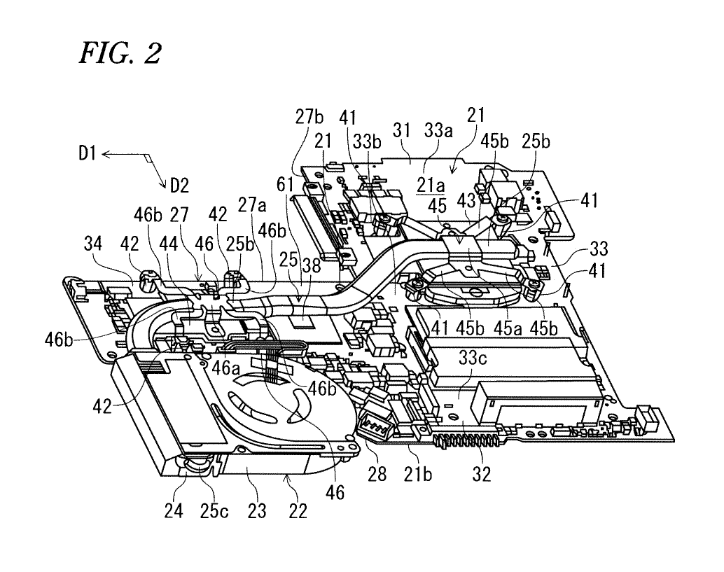

As shown in FIG. 2, a circuit board 21 and a heat dissipation module 22 are housed in the case 5 of the body unit 2. The heat dissipation module 22 is of the remote heat exchanger (RHE) type that includes a cooling fan 23, a heat sink 24 and a heat pipe 25.

The circuit board 21 is, e.g., a main board. The circuit board 21 has a first face 21a and a second face 21b located on the opposite side of the first face 21a. According to the exemplary embodiment, the first face 21a is a bottom face. The second face 21b is a top face. Alternatively, it is possible that the first face 21a is the top face and that the second face 21b is the bottom face.

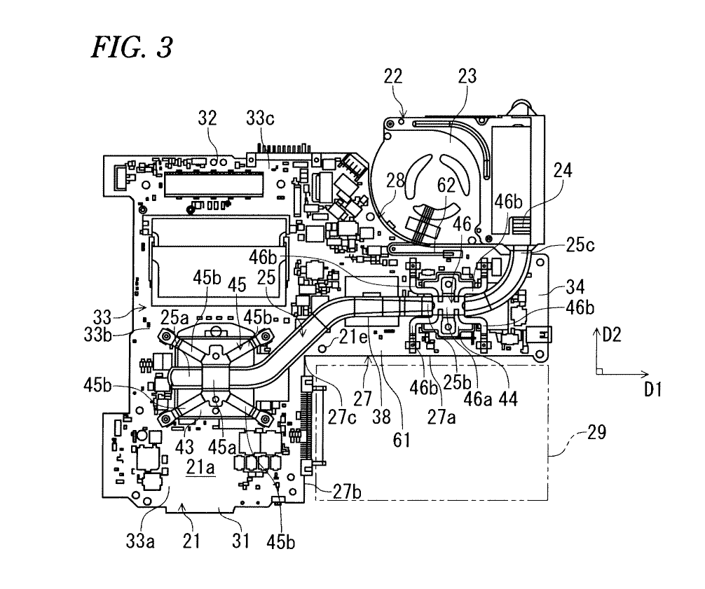

As shown in FIG. 3, the circuit board 21 has a first cutout portion 27 and a second cutout portion 28. The first cutout portion 27 is cut out along an outer shape of a storage device 29 and is formed into a rectangular shape. An example of the storage device 29 is a hard disk drive (HDD). The second cutout portion 28 is cut out along outer shapes of the cooling fan 23 and the heat sink 24.

The first cutout portion 27 has a first straight portion 27a and a second straight portion 27b extending in a direction intersecting with (e.g., a direction substantially perpendicular to) the first straight portion 27a. A substantially-right-angle 27c is provided at a point of intersection between the first straight portion 27a and the second straight portion 27b.

The circuit board 21 has a first end portion 31 and a second end portion 32 located on the opposite side of the first end portion 31. The first cutout portion 27 is formed along the first end portion 31. The second cutout portion 28 is formed along the second end portion 32. Consequently, the circuit board 21 has a first part 33 which is not located between the first cutout portion 27 and the second cutout portion 28, and a second part 34 which is located between the first cutout portion 27 and the second cutout portion 28. The second part 34 is a narrow portion that is narrow in width and weak in strength, as compared with the first part 33.

As shown in FIG. 3, the first part 33 includes a first region 33a, a second region 33b, and a third region 33c. A direction directed from the first part 33 to the second part 34 is defined as a first direction D1. A second direction D2 is defined as a direction substantially perpendicular to the first direction D1. The first region 33a is an area adjacent in the first direction D1 to the first cutout portion 27. The second region 33b is an area adjacent in the first direction D1 to the second part 34. The third region 33c is an area adjacent in the first direction D1 to the second cutout portion 28.

The first direction D1 is, e.g., a longitudinal direction of the circuit board 21. The second direction D2 is, e.g., a shorter-side direction of the circuit board 21. The second part 34 of the circuit board 21 extends in the first direction D1 from a center of the circuit board 21. The first cutout portion 27 and the second cutout portion 28 are arranged along the second direction D2.

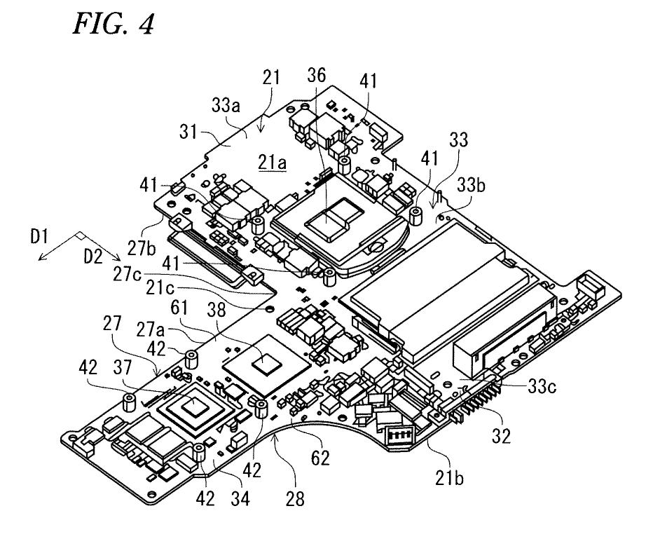

As shown in FIG. 4, a first heating element 36, a second heating element 37 and a third heating element 38 are mounted on the first face 21a. The first heating element 36 is, e.g., a central processing unit (CPU). The second heating element 37 is, e.g., a video graphics array (VGA). The third heating element 38 is, e.g., a platform controller hub (PCH). Heating elements to which the exemplary embodiment can be applied are not limited to the above examples. Various components required to dissipate heat can appropriately be applied to such heating elements.

The first heating element 36 is arranged on the first part 33 and straddles the first region 33a and the second region 33b. That is, at least a part of the first heating element 36 is located on the first region 33a. The second heating element 37 is arranged on the second part 34. The third heating element 38 straddles the first part 33 and the second part 34. That is, at least a part of the third heating element 38 is arranged on the second part 34.

As shown in FIG. 4, four first-studs 41 surrounding the first heating element 36 are attached to the circuit board 21 around the first heating element 36. The four first-studs 41 are arranged corresponding to the four corner portions of the substantially rectangular first heating element 36, respectively. On the other hand, four second-studs 42 surrounding the second heating element 37 are attached to the circuit board 21 around the second heating element 37. The four second-studs 42 are arranged corresponding to the four corner portions of the substantially rectangular second heating element 37, respectively.

As shown in FIGS. 2 and 3, a first heat-receiving member 43 faces and is thermally connected to the first heating element 36. A second heat-receiving member 44 faces and is thermally connected to the second heating element 37. Each of the first heat-receiving element 43 and the second heat-receiving element 44 is, e.g., a metallic heat-receiving plate.

The heat pipe 25 is an example of a heat conductive member and faces the first face 21a of the circuit board 21. The heat pipe 25 has a first heat-receiving portion 25a connected to the first heat-receiving member 43, a second heat-receiving portion 25b connected to the second heat-receiving member 44, and a heat dissipation portion 25c connected to the heat sink 24. The heat pipe 25 is thermally connected to each of the first heating element 36, the second heating element 37, and the heat sink 24, and transfers the heat of the first heating element 36 and the second heating element 37 to the heat sink 24. The third heating element 38 adopts, e.g., natural heat dissipation. Instead of this configuration, the third heating element 38 may thermally be connected to the heat pipe 25.

As shown in FIGS. 2 and 3, a first pressing member 45 is attached to each first stud 41. The first pressing member 45 has a pressing portion 45a facing the heat pipe 25, and, e.g., four fixing portions 45b which extend from the pressing portion 45a and are respectively fixed to the first studs 41. The pressing portion 45a and the fixing portions 45b cooperate with one another and function as a plate spring. The fixing portions 45b are fixed to the first studs 41, respectively, so that the pressing portion 45a presses the heat pipe 25 and the first heat-receiving member 43 against the first heating element 36. Consequently, the heat pipe 25 is more strongly thermally connected to the first heating element 36.

A second pressing member 46 is attached to second studs 42. The second pressing member 46 has a pressing portion 46a facing the heat pipe 25, and, e.g., four fixing portions 46b which extend from the pressing portion 46a and are respectively fixed to the second studs 42. The pressing portion 46a and the fixing portions 46b cooperate with one another and function as a plate spring. The fixing portions 46b are fixed to the second studs 42, respectively, so that the pressing portion 46a presses the heat pipe 25 and the second heat-receiving member 44 against the second heating element 37. Consequently, the heat pipe 25 is more strongly thermally connected to the second heating element 37.

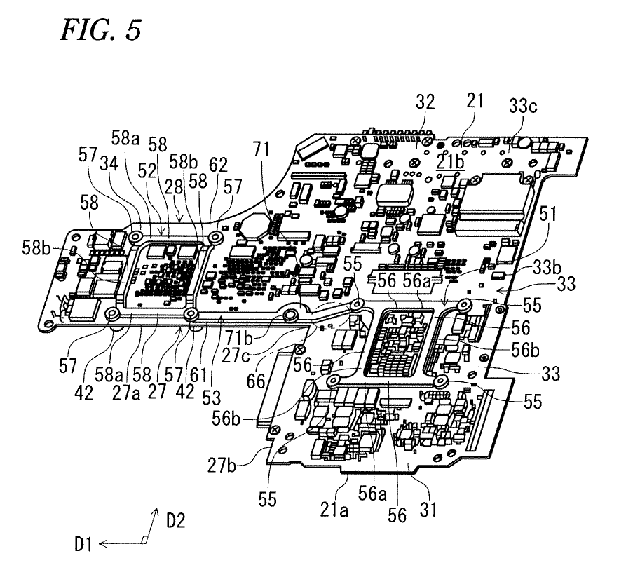

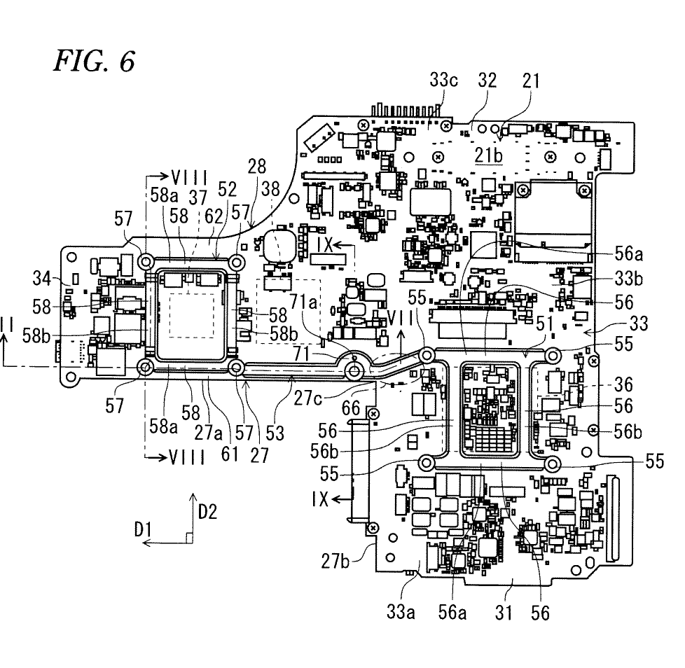

As shown in FIGS. 5 and 6, a first back plate 51, a second back plate 52 and a connecting portion 53 are attached to the second face 21b of the circuit board 21. The first back plate 51, the second back plate 52 and the connecting portion 53 are integrally formed of a metallic material and larger in rigidity, as compared with the circuit board 21.

The first back plate 51 is an example of a first reinforcing portion and corresponds to the first heating element 36. The first back plate 51 is provided on the first part 33 of the circuit board 21. The first back plate 51 has four fixing portions 55, and four beam portions 56 that connect the four fixing portions 55 like a frame. “Connecting like a frame” according to the exemplary embodiment is not limited to forming like a window frame similar to the second back plate 52 shown in FIG. 5, and includes forming like an anomalous frame similar to the first back plate 51. That is, it is sufficient for implementing “connecting like a frame” according to the exemplary embodiment that the frame has two beam portions extending in substantially parallel with each other and additional two beam portions laid across the former two beam portions.

The four beam portions 56 of the first back plate 51 according to the exemplary embodiment include two first-beam portions 56a extending in the first direction D1, and two second-beam portions 56b extending in the second direction D2. The two first-beam portions 56a extend substantially in parallel with each other. The two second-beam portions 56b are laid across the first-beam portions 56a.

All the four beam portions 56 of the first back plate 51 extend along and are substantially closely attached to the second face 21b of the circuit board 21. The case of causing each beam portion to “be substantially closely attached to” the surface of the circuit board includes that of lapping each beam portion over the surface thereof by inserting, e.g., an insulator film therebetween in addition to that of causing each beam portion to “be directly in contact with” the surface thereof. That is, the state of causing each beam portion to “be substantially closely attached to” the surface of the circuit board means a state in which substantially no gap promoting bending of the circuit board exists between the back plate (or a connecting portion which will be described below) and the circuit board.

The fixing portions 55 are arranged at positions respectively corresponding to the first studs 41. FIG. 8 illustrates an example of the second back plate 52. Similarly to this example, the fixing portions 55 of the first back plate 51 are fixed to the circuit board 21 with the first studs 41, respectively. Particularly, each fixing portion 55 has a screw hole 59. The screw hole 59 is an example of an engaging portion. The circuit board 21 has an insertion hole 21c facing the screw hole 59. Each first stud 41 has a screw portion 60. The first stud 41 is an example of a fixing member.

The screw portion 60 of each first stud 41 is inserted into the associated insertion hole 21c of the circuit board 21 and engages with the screw hole 59 of the associated fixing portion 55. Thus, the first back plate 51 is fixed to the circuit board 21. More specifically, the first pressing member 45 is fixed to the first back plate 51 via the first studs 41. The first back plate 51 may be fixed with fixing members other than the studs.

The second back plate 52 is an example of a second reinforcing portion and corresponds to the second heating element 37. The second back plate 52 is provided on the second part 34 of the circuit board 21. The second back plate 52 is located across the first cutout portion 27 from the first back plate 51. That is, the second back plate 52 is located farther from the first back plate 51 than at least a part of the first cutout portion 27.

The second back plate 52 has four fixing portions 57 and four beam portions 58 connecting the four fixing portions 57 like a frame. The four beam portions 58 include two first-beam portions 58a extending in the first direction D1, and two second-beam portions 58b extending in the second direction D2. The two first-beam portions 58a extend in substantially parallel with each other. The two second-beam portions 58b are laid across the first-beam portions 58a.

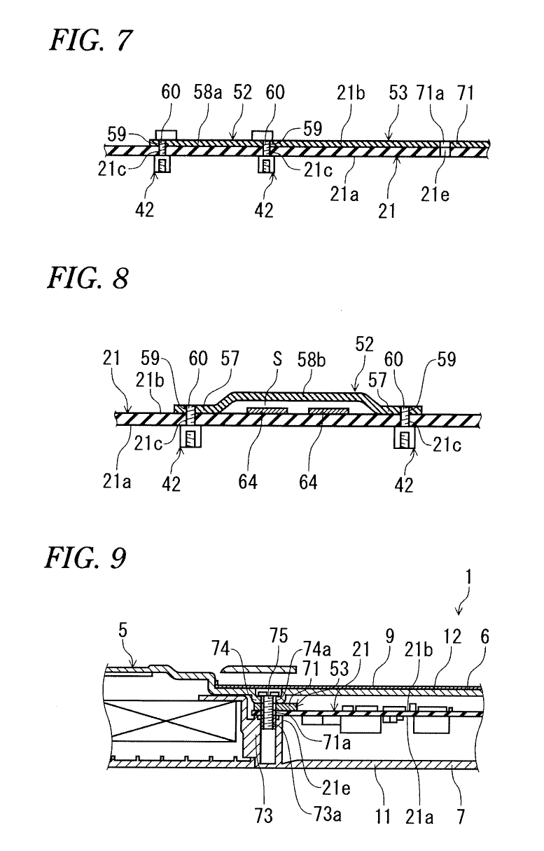

As shown in FIGS. 5 and 7, the two first-beam portions 58a of the second back plate 52 extend along and are substantially closely attached to the second face 21b of the circuit board 21. As illustrated in FIG. 6, the circuit board 21 has a first end portion 61 facing the first cutout portion 27, and a second end portion 62 facing the second cutout portion 28. The two first-beam portions 58a are divided from each other and placed on and extend along the first end portion 61 and the second end portion 62, respectively.

On the other hand, as shown in FIGS. 5 and 8, the two second-beam portions 58b of the second back plate 52 are floated from the circuit board 21, so that a gap S is formed between each second-beam portion 58b and the circuit board 21. For example, a plurality of electronic components 64 are arranged on a region overlapping with the second-beam portion 58b.

The fixing portions 57 are arranged at positions respectively corresponding to the second studs 42. As shown in FIG. 8, the fixing portions 57 are fixed to the circuit board 21 with the second studs 42, respectively. Particularly, each fixing portion 57 has a screw hole 59. The screw hole 59 is an example of the engaging portion. The circuit board 21 has an insertion hole 21c facing the screw hole 59. Each second stud 42 has a screw portion 60. Each second stud 42 is an example of the fixing member.

The screw portion 60 of each second stud 42 is inserted into the associated insertion hole 21c of the circuit board 21 and engages with the screw hole 59 of the associated fixing portion 57. Thus, the second back plate 52 is fixed to the circuit board 21. More specifically, the second pressing member 46 is fixed to the second back plate 52 via the second studs 42. The second back plate 52 may be fixed with fixing members other than the studs.

As shown in FIGS. 5 and 6, the connecting portion 53 is provided between the first back plate 51 and the second back plate 52 and connects both the back plates 51 and 52 to each other. The connecting portion 53 extends between a corner portion (i.e., the fixing portion 55) of the first back plate 51 and that (i.e., the fixing portion 57) of the second back plate 52. The connecting portion 53 extends from the first part 33 to the second part 34 of the circuit board 21.

As shown in FIG. 7, the connecting portion 53 extends along and is substantially closely attached to the second face 21b of the circuit board 21. In the exemplary embodiment, the connecting portion 53 is substantially closely attached to the second face 21b of the circuit board 21 over the entire length thereof.

As shown in FIGS. 5 and 6, at least a part of the connecting portion 53 extends along the first cutout portion 27 like a straight-line. More specifically, at least a part of the connecting portion 53 extends along the outer shape of the first cutout portion 27 (an edge part of the first cutout portion 27, i.e., the first straight portion 27a). As shown in FIGS. 5 and 6, the connecting portion 53 extends on an extension of the first-beam portion 58a of the second back plate 52. That is, the connecting portion 53 is connected to the first-beam portion 58a like a straight-line.

As shown in FIG. 6, the circuit board 21 has a weak part 66 which is provided in the vicinity of the corner 27c of the first cutout portion 27 and can least withstand bending, among parts thereof. The weak part 66 is a portion on which e.g., stress is concentrated when the circuit board 2 bends, and at which the breakage of a wiring-pattern and solder cracks tend to occur. The connecting portion 53 is arranged to pass through the weak part 66.

As shown in FIG. 5, a fixing portion 71 is provided halfway (at a middle portion of) the connecting portion 53. The fixing portion 71 is formed like, e.g., a substantially semi-circle and wide in width, as compared with other parts of the connecting portion 53. The fixing portion 71 is provided at a position shifted from the corner 27c of the first cutout portion 27. The fixing portion 71 does not face the corner 27c of the first cutout portion 27. The fixing portion 71 has a first insertion hole 71a. As shown in FIG. 7, the circuit board 21 has a second insertion hole 21e facing the first insertion hole 71a.

As shown in FIG. 9, the connecting portion 53 and the circuit board 21 are placed between the base 11 and the cover 12 which configure the case 5. The base 11 faces the connecting portion 53 and the circuit board 21 and has, e.g., a first support portion 73 supporting the circuit board 21 from below. The cover 12 faces the connecting portion 53 and the circuit board 21 and has, e.g., a second support portion 74 supporting the connecting portion 53 from above.

The first support portion 73 has, e.g., a screw hole 73a. The screw hole 73a is an example of the engaging portion. The second support portion 74 has, e.g., a third insertion hole 74a. A screw 75 is engaged with the screw hole 73a via the third insertion whole 74a, the first insertion hole 71a, and the second insertion hole 21e. Thus, the base 11, the cover 12, the connecting portion 53, and the circuit board 21 are fastened and fixed together. Consequently, the fixing portion 71 of the connecting portion 53 is fixed to the circuit board 21 and also fixed to the case 5. The screw 75 is an example of the fixing member.

As shown in FIG. 6, the first heating element 36 is arranged on a region surrounded by the four fixing portions 55 of the first back plate 51 and reinforced by the first back plate 51. The second heating element 37 is arranged on a region surrounded by the four fixing portions 57 of the second back plate 52 and reinforced by the second back plate 52.

A part of the third heating element 38 is arranged on a right-triangle-shaped region surrounded by two of the four fixing portions 57 of the second back plate 52 and the fixing portion 71 of the connecting portion 53. The third heating element 38 is arranged along the second beam-portion 58b of the second back plate 52 and the connecting portion 53. Consequently, the third heating element 38 is reinforced by the second back plate 52 and the connecting portion 53. The entire third heating element 38 can be arranged on a region surrounded by the two fixing portions 57 of the second back plate 52 and the fixing portion 71 of the connecting portion 53.

The electronic apparatus 1 of such a configuration can reduce stress applied to the circuit board 21. Reduction in thickness and size of the electronic apparatus 1 sometimes results in a complex configuration (e.g., a cut-out shape) of the circuit board 21. The circuit board 21 of such a complex configuration is flexible and susceptive to large stress. When the heat dissipation module is mounted on the circuit board, a load applied to the circuit board increases. Thus, when the circuit board is held by, e.g., hand, a load is applied to the circuit board, so that the circuit board is bent and stress is applied to the circuit board.

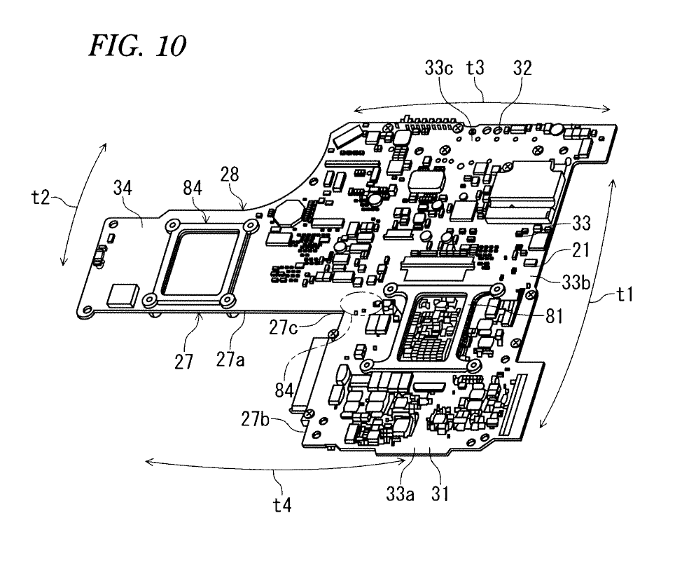

FIG. 10 shows the circuit board 21 on which the first back plate 81 and the second back plate 82 are assumed to be mounted independent of each other. On the circuit board 21, a part 84 in the vicinity of the corner 27c of the first cutout portion 27 is most subjected to bending stress when torsions in the directions t1 and t2 and those in the directions t3 and t4 are caused around the part 84. The bending-stress may cause the breaking of the wiring pattern on the board through a process in which the wiring pattern on the board is subjected to the stress. The bending stress may also cause a solder crack through a process in which soldered portions of mounted components around the part 84 are subjected to the stress. Such a minute amount of stress may damage the long-term reliability of products.

On the other hand, the circuit board 21 according to the exemplary embodiment is provided with the connecting portion 53 connecting the first back plate 51 and the second back plate 52 to each other. Consequently, the strength of the first back plate 51 itself and that of the second back plate 52 itself are increased. In addition, the circuit board 21 is reinforced by the connecting portion 53 even at the part between the first back plate 51 and the second back plate 52. Thus, the circuit board 21 becomes hard to bend.

Accordingly, even when a force to bend the circuit board 21 acts thereon, the circuit board 21 is difficult to be twisted (or bent). Stress acting on the circuit board 21 is reduced. Thus, the breaking of the wiring pattern on the circuit board 21 and the occurrence of a solder crack can be suppressed. Consequently, the reliability of products can be improved.

When the connecting portion 53 extends along the cutout portion 27, the weak part 66 generated around the cutout portion 27 is reinforced directly (or immediately adjacently). Thus, the circuit board 21 becomes more difficult to bend. In addition, when the connecting portion 53 extends along the cutout portion 27, a mounting area can easily be secured in a central region of the circuit board 21. Thus, the high-density packaging of components can be achieved. When the connecting portion 53 extends along the surface of the circuit board 21, no gap for promoting the bending of the circuit board 21 exists between the connecting portion 53 and the circuit board 21. Thus, the circuit board 21 becomes more difficult to bend.

When the connecting portion 53 has the fixing portion 71 fixed to the circuit board 21, the connecting portion 53 and the circuit board 21 are more integrated. Thus, the circuit board 21 is difficult to be shifted from the connecting portion 53. In addition, the circuit board 21 becomes more difficult to bend. When the fixing portion 71 is further fixed to the case 5, the circuit board 21 is further supported by the case 5. Thus, the circuit board 21 becomes more difficult to bend.

As described above, stress concentration tends to occur at the corner 27c of the cutout portion 27. The vicinity of the corner 27c tends to be weak. When, e.g., the insertion hole 71a of the fixing portion 71 is provided immediately adjacent to such a corner 27c of the cutout portion 27, a part surrounding the corner 27c may become weaker. On the other hand, the fixing portion according to the exemplary embodiment is provided at a position shifting from the corner 27c of the cutout portion 27. Thus, the fixing portion 71 can fix the connecting portion 53 to the circuit board 21 while maintaining the strength of the circuit board 21.

When the third heating element 38 is arranged along the connecting portion 53, a part surrounding the third heating element 38 is reinforced by the connecting portion 53. That is, the warpage of an area around the third heating element 38 on the circuit board 21 is small. Thus, stress acting on the third heating element 38 is small.

In the exemplary embodiment, a part of the third heating element 38 is arranged on an area surrounded by two of the fixing portions 57 of the second back plate 52 and the fixing portion 71 of the connecting portion 53. Thus, the warpage of the area around the third heating element 38 on the circuit board 21 becomes further smaller. The stress acting on the third heating element becomes further smaller.

The second back plate 52 includes the two first-beam portions 58a extending along the surface of the circuit board 21, and the two second-beam portions 58b floated up from the circuit board 21. Such a second back plate 52 is enhanced in the strength in a bending direction thereof, as compared with a back plate having four beam portions all of which are closely attached to the circuit board. In addition, a part (i.e., the second-beam portion 58b) of the second back plate 52 is raised. Thus, even a part overlapping with the second back plate 52 is configured such that components can be mounted thereon. Consequently, higher-density packaging of components can further be achieved.

However, when each of all beam-portions of a back plate has a gap from the circuit board 21, the circuit board 21 may bend by an amount corresponding to the gap. Thus, the second back plate 52 according to the exemplary embodiment is configured so that the two first-beam portions 58a arranged in a direction (longitudinal direction) in which the bending of the circuit board 21 relatively easily occurs are substantially closely attached to the circuit board 21, and that the two first-beam portions 58b arranged in a direction (shorter-side direction) in which the bending of the circuit board 21 is relatively difficult to occur are floated up from the circuit board 21. Consequently, both of the securement of the mounting area and the reinforcement of the circuit board 21 can simultaneously be achieved in a balanced manner.

When the connecting portion 53 extends on an extension of the first-beam portion 58a of the second back plate 52, the beam-portion is formed to continuously extend from the second back plate 52 to the connecting portion 53. Thus, the circuit board 21 is more difficult to bend.

When the circuit board 21 is provided with the first pressing member 45 fixed to the first back plate 51 to press the heat pipe 25, and with the second pressing member 46 fixed to the second back plate 52 to press the heat pipe 25, the first pressing member 45 and the second pressing member 46 cause a bending force to act on the circuit board 21 via the heat pipe 25. When the first back plate 51 and the second back plate 52 are connected to each other by the connecting portion 53 in the circuit board 21 of such a configuration, a beam portion counteracting the bending force is formed to extend from the first heating element 36 to the second heating element 37. Thus, the warpage of the circuit board 21 becomes further smaller.

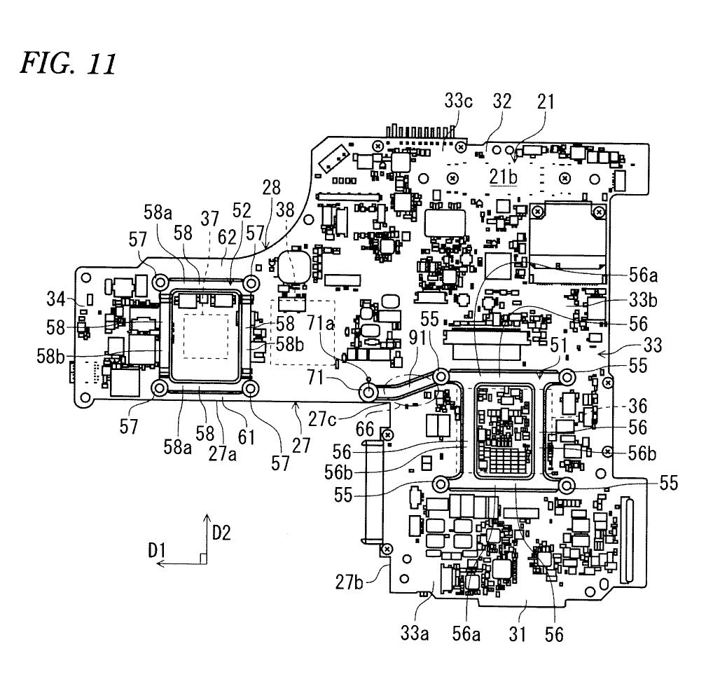

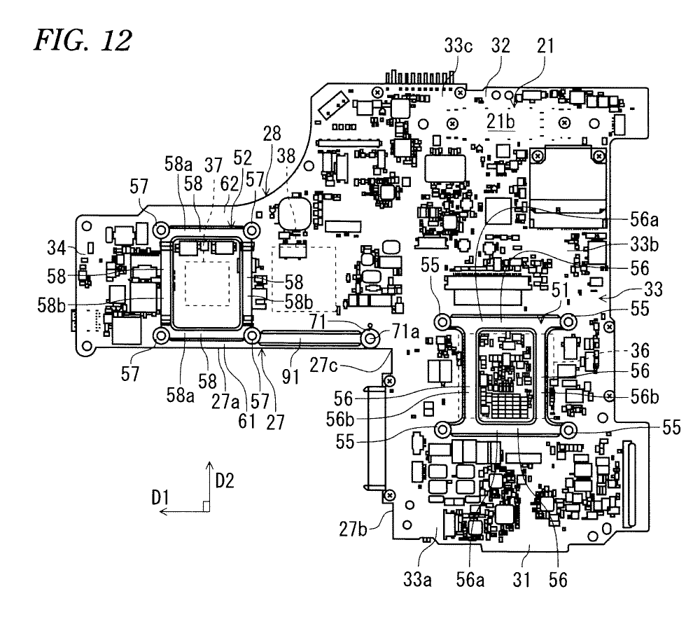

Next, two modifications of the electronic apparatus 1 are described with reference to FIGS. 11 and 12. A component having a function which is the same as or similar to that of the component of the above exemplary embodiment is designated with the same reference numeral. Thus, the description of such a component is omitted. Components of the modifications other than the following components are the same as the associated components of the above exemplary embodiment.

FIG. 11 shows a circuit board 21 of the electronic apparatus 1 according to a first modification example. As shown in FIG. 11, the first back plate 51 has, e.g., an extension portion 91 extending from the fixing portion 55 to the opposite side of the first-beam portion 56. The fixing portion 71 is provided at a leading-end of the extension portion 91. At least a part of the third heating element 38 is arranged on a region surrounded by the two fixing portions 57 of the second back plate 52 and the fixing portion 71 of the extension portion 91. Consequently, the third heating element 38 is reinforced, similarly to the above exemplary embodiment.

FIG. 12 shows a circuit board 21 of the electronic apparatus 1 according to a second modification example. As shown in FIG. 12, the second back plate 52 has an extension portion 91 extending from, e.g., the fixing portion 57 to the opposite side of the first-beam portion 58. The extension portion 91 extends along the third heating element 38. The fixing portion 71 is provided at a leading-end of the extension portion 91. At least a part of the third heating element 38 is arranged on a region surrounded by the two second fixing portions 57 of the second back plate 52 and the fixing portion 71 of the extension portion 91. Consequently, the third heating element 38 is reinforced, similarly to the above exemplary embodiment.

In the foregoing description, the electronic apparatus 1 according to one exemplary embodiment has been described. However, the exemplary embodiment is not limited thereto. The invention is not limited to the above embodiment as it is, but can be embodied by changing the components thereof without departing from the substance in the implementation step.

It is not always necessary that the connecting portion 53 extends along the circuit board 21. The fixing portion 71 of the connecting portion 53 can be fixed only to the case 5. Alternatively, the fixing portion 71 can be fixed only to the circuit board 21. The fixing portion 71 of the connecting portion 53 can appropriately be omitted. The heat dissipation module 22 is not an indispensable component and can appropriately be omitted. The second-beam portion 58b of the second back plate 52 can be substantially closely attached to the circuit board 21.

While certain embodiment has been described, the exemplary embodiment has been presented by way of example only, and is not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A circuit module comprising:
a circuit board provided with a mounting region on which a heating element is mounted;
a reinforcing portion attached to the circuit board, and configured to reinforce the mounting region; and
four fixing portions configured to fix the reinforcing portion and the circuit board, wherein
the reinforcing portion includes four beam portions configured to connect the four fixing portions like a frame, and
the four beam portions include two first-beam portions configured to extend along a surface of the circuit board, and two second-beam portions configured to be floated up from the circuit board.

2. The module of claim 1, wherein
the first-beam portions are configured to extend in a longitudinal direction of the circuit board, and
the second-beam portions are configured to extend in a shorter-side direction of the circuit board.

3. The module of claim 2, wherein
the reinforcing portion includes a extension portion, and
the extension portion is configured to extend substantially on an extension of one of the first-beam portions.

4. An electronic apparatus comprising:
a case;
a circuit board housed in the case and provided with a mounting region on which a heating element is mounted;
a reinforcing portion attached to the circuit board, and configured to reinforce the mounting region; and
four fixing portions configured to fix the reinforcing portion and the circuit board, wherein
the reinforcing portion includes four beam portions configured to connect the four fixing portions like a frame, and
the four beam portions include two first-beam portions configured to extend along a surface of the circuit board, and two second-beam portions configured to be floated up from the circuit board.

5. A circuit module comprising:
a circuit board including a cutout portion provided with a corner portion;
a first reinforcing portion attached to the circuit board;
a second reinforcing portion attached to the circuit board at a position differing from a position at which the first reinforcing portion is attached to the circuit board;
a connecting portion configured to connect to the first reinforcing portion and the second reinforcing portion, in which at least a part of the connecting portion is configured to extend along the cutout portion including a region in vicinity of the corner portion; and
a fixing portion having a shape emanating from the connecting portion to a central portion of the circuit board, and configured to fix the connecting portion and the region in the vicinity of the corner portion.

6. The module of claim 5, wherein
the circuit board includes a first heating element mounted on a region surrounded by the first reinforcing portion, the second reinforcing portion and the connecting portion.

7. The module of claim 6, wherein
the connecting portion is configured to extend along a surface of the circuit board.

8. The module of claim 7, wherein
the fixing portion is configured to be fixed to the case.

9. The module of claim 6, wherein
the fixing portion is provided at a position shifted from the corner portion of the cutout portion.

10. The module of claim 6 further comprising:
a second heating element mounted on the circuit board,
wherein the second heating element is arranged along the connecting portion.
